(19) United States
(12) Patent Application Publication
(10) Pub. No.: US 2011/0129957 A1
(43) Pub. Date: Jun. 2, 2011

(54) METHOD OF MANUFACTURING SOLAR CELL

(76) Inventor: Byoung-Dong KIM, Asan-si (KR)

(21) Appl. No.: 12/789,591

(22) Filed: May 28, 2010

(30) Foreign Application Priority Data
Nov. 30, 2009 (KR) 10-2009-0116638

(51) Int. Cl. H01L 31/18

(52) U.S. Cl. 438/84; 438/95; 257/E31.004; 257/E31.032

(57) ABSTRACT

A solar cell manufacturing method is provided. A solar cell manufacturing method according to an exemplary embodiment of the present invention includes: forming a first electrode on a substrate, forming a precursor including copper (Cu), gallium (Ga), and indium (In) on the first electrode, supplying selenium (Se) to the precursor to form a preliminary light absorption layer, depositing at least one of gallium or indium on the preliminary light absorption layer, supplying selenium (Se) to the preliminary light absorption layer deposited with the at least one of gallium and indium to form a light absorption layer and forming a second electrode on the light absorption layer.

### CROSS-REFERENCE TO RELATED APPLICATION

This application claims priority to Korean Patent Application No. 10-2009-0116638 filed on Nov. 30, 2009, the entire disclosure of which is hereby incorporated by reference herein in its entirety.

### BACKGROUND OF THE INVENTION

(a) Technical Field

The present disclosure relates to a method for manufacturing a solar cell.

(b) Description of the Related Art

A solar cell may convert solar energy to electrical energy by using a photoelectric effect. The solar cell has been spotlighted as a clean energy or next-generation energy provider that can be a substitute for fossil energy that leads to a greenhouse effect due to a discharge of carbon dioxide (CO₂) and for atomic energy that pollutes the earth's environment such as by air pollution due to radioactive waste.

The solar cell may generate electricity using two kinds of semiconductors called a P-type semiconductor and an N-type semiconductor, and may be divided into various kinds according to a material used as a light absorption layer.

In the general structure of the solar cell, the sequence of a front transparent conductive film, a PN film, and a rear reflecting electrode film are deposited on a substrate. If sunlight is incident to the solar cell having this structure, electrons may be collected in the N layer and holes may be collected in the P layer, thereby generating a current.

A compound solar cell (for example a CIGS compound solar cell) is a high efficiency solar cell that converts sunlight into electricity without using silicon, differently from the existing silicon-based solar cell, by depositing copper, indium, gallium, and selenium compounds on a glass substrate or a flexible substrate such as stainless steel, aluminum, and the like.

Here, when depositing the CIGS (Cu, In, Ga, Se) compound, evaporation or sputtering may be used. To form the solar cell having high efficiency, optimization of the composition ratio of copper (Cu), indium (In), and gallium (Ga) may be necessary to increase crystallization, and to reduce defects between interfaces.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention may provide a method of manufacturing a CIGS solar cell with high efficiency.

A solar cell manufacturing method according to an exemplary embodiment of the present invention includes: forming a first electrode on a substrate, forming a precursor including copper (Cu), gallium (Ga), and indium (In) on the first electrode, supplying selenium (Se) to the precursor to form a preliminary light absorption layer; depositing at least one of gallium and indium on the preliminary light absorption layer, supplying selenium (Se) to the preliminary light absorption layer deposited with the at least one of gallium and indium to form a light absorption layer and forming a second electrode on the light absorption layer.

The precursor may be formed for a composition ratio corresponding to the copper/(gallium+indium) to be more than about 1.2.

The forming of the preliminary light absorption layer may include forming a CIGS (Cu, In, Ga, Se) compound and a copper selenide (CuSe) compound.

The depositing of at least one of gallium and indium on the preliminary light absorption layer may include controlling a value of copper/(gallium+indium) corresponding to the composition ratio of the light absorption layer to be less than about 1.

The forming of the precursor may include forming a first layer including copper and at least one of gallium and indium on the first electrode, and forming a second layer including at least one of gallium and indium on the first layer.

The forming of the first and second layers may use sputtering.

The forming of the preliminary light absorption layer by supplying selenium (Se) to the precursor may include a heat treatment.

The forming of the preliminary light absorption layer may include forming a CuSe compound, and the CuSe compound may be a liquid phase.

The CuSe compound may be positioned at the interface between the CIGS compound and the first electrode.

The forming of the light absorption layer may include forming a CIGS compound by reacting the CuSe compound and at least one of gallium and indium.

The first electrode may be formed of a reflective metal.

The second electrode may be formed of a transparent conductive material.

Forming a buffer layer between the light absorption layer and the second electrode may be further included.

According to an exemplary embodiment of the present invention, the CuSe compound is formed in the middle process and the selenization process of two steps is executed, thereby manufacturing the solar cell of high efficiency.

### BRIEF DESCRIPTION OF THE DRAWINGS

Exemplary embodiments of the present invention can be understood in more detail from the following description taken in conjunction with the attached drawing in which:

FIG. 1 is a flowchart of a manufacturing method of a solar cell according to an exemplary embodiment of the present invention.

FIG. 2 to FIG. 8 are cross-sectional views of a manufacturing method of a solar cell according to an exemplary embodiment of the present invention.

### DESCRIPTION OF REFERENCE NUMERALS INDICATING PRIMARY ELEMENTS IN THE DRAWINGS

10 substrate
20 first electrode
30 first layer
40 second layer
31 preliminary light absorption layer
31a CIGS compound layer
31b CuSe compound layer
50 third layer
32 light absorption layer
32a CIGS crystallization layer
60 buffer layer
70 second electrode
P precursor

### DETAILED DESCRIPTION OF THE EXEMPLARY EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. Like reference numerals designate like elements throughout the specification.

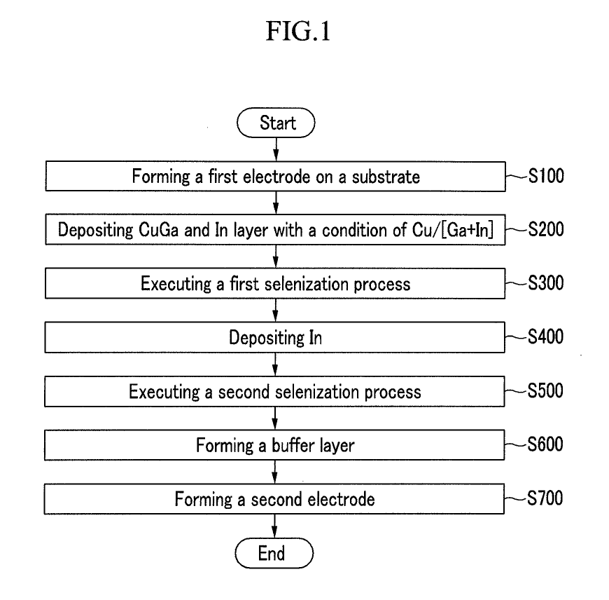

FIG. 1 is a flowchart of a manufacturing method of a solar cell according to an exemplary embodiment of the present invention.

Referring to FIG. 1, the first electrode is formed on a glass substrate (S100). The first electrode may be made of, for example, a metal material that reflects light.

A copper-gallium (CuGa) compound and indium (In) are sequentially deposited through sputtering on the first electrode (S200). Here, the copper-gallium (CuGa) compound and the indium (In) constitute a precursor, and the precursor may be formed to have a composition ratio of more than about 1.2 corresponding to the copper/(gallium+indium).

The first selenization process is executed while heat-treating the precursor (S300). A CIGS (Cu, In, Ga, Se) compound is formed after executing the first selenization process, and the copper remaining because of abundant copper after forming the CIGS compound is combined with selenium (Se), thereby forming a copper selenide (CuSe) compound. The CIGS compound and the CuSe compound may form a preliminary light absorption layer.

Indium (In) is additionally deposited on the preliminary light absorption layer (S400). Here, the content of the added indium (In) may be controlled for the composition ratio corresponding to copper/(gallium+indium) of the CIGS compound that is finally formed to be less than about 1.0.

The second selenization process is executed while heat-treating the preliminary light absorption layer S500. Accordingly, a light absorption layer made of the CIGS compound having a density configuration is formed.

A buffer layer is formed on the light absorption layer (S600).

The second electrode is formed on the buffer layer (S700). The second electrode may be made of a material having good light transmittance and good electrical conductivity. An upper substrate may be additionally formed on the second electrode.

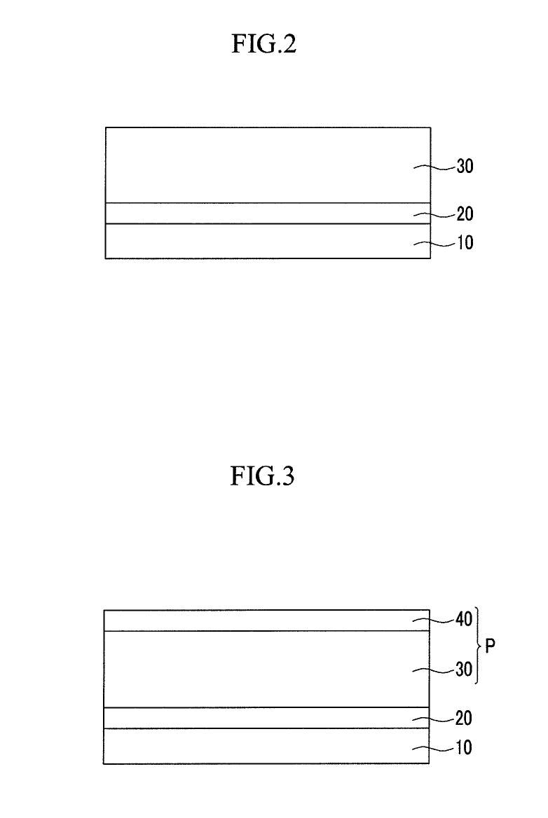

FIG. 2 to FIG. 8 are cross-sectional views of a manufacturing method of a solar cell according to an exemplary embodiment of the present invention.

A manufacturing method of a solar cell according to an exemplary embodiment of the present invention will be described with reference to FIG. 2 to FIG. 8.

Referring to FIG. 2, a first electrode 20 is formed on a substrate 10. For example, the substrate 10 may be made of a ceramic material, a metal such as a stainless steel, or an amorphous material such as glass. The first electrode 20 may be made of a reflective conductive metal such as, for example, aluminum, copper, or molybdenum.

A first layer 30 is formed on the first electrode 20 by, for example, sputtering a compound of copper-gallium (CuGa). In an exemplary embodiment of the present invention, the first layer 30 is formed of the compound of copper-gallium (CuGa). However, the first layer 30 may be made of a compound of copper-indium (CuIn) in another exemplary embodiment.

Referring to FIG. 3, a second layer 40 is formed on the first layer 30 by depositing at least one of gallium (Ga) and indium (In) through, for example, sputtering. Here, the first layer 30 and the second layer 40 constitute the precursor P of a light absorption layer. According to an exemplary embodiment of the present invention, the precursor P including the first layer 30 and the second layer 40 is formed to have a composition ratio of more than about 1.2 corresponding to copper/(gallium+indium). That is, the copper (Cu) is relatively plentiful compared with gallium (Ga) and indium (In).

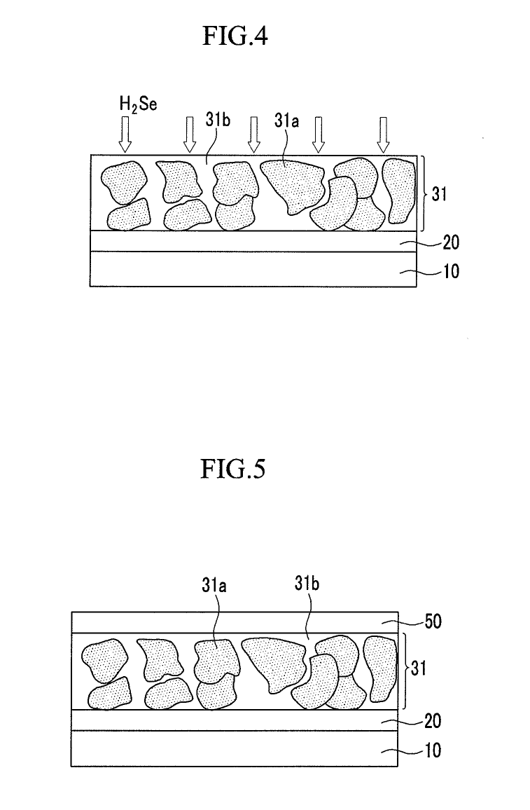

Referring to FIG. 4, a preliminary light absorption layer 31 is formed by supplying selenium (Se) while heat-treating the precursor P. The preliminary light absorption layer 31 includes a CIGS compound layer 31a and a CuSe compound layer 31b. In detail, the selenium (Se) supplied while heat-treating the precursor P is reacted with copper (Cu), gallium (Ga), and indium (In) included in the precursor P thereby forming the CIGS compound layer 31a and the CuSe compound layer 31b.

The heat treatment temperature may be a high temperature of, for example, about 500 degrees to about 600 degrees. The CuSe compound layer 31b is changed into a liquid at the high temperature thereby filling in voids between the CIGS compound layer 31a. Here, the CuSe compound may fill in voids generated at the interface between the first electrode 20 and the CIGS compound layer 31a.

Referring to FIG. 5, gallium (Ga) or indium (In) is additionally deposited on the preliminary light absorption layer 31 through, for example, sputtering to form a third layer 50. According to an exemplary embodiment of the present invention, the light absorption layer may be finally formed to have a composition ratio of copper/(gallium+indium) of less than about 1. For obtaining this composition ratio, the amount of gallium or indium deposited on the preliminary light absorption layer 31 may be controlled. When the composition ratio of copper/(gallium+indium) is about 0.9 in the CIGS solar cell, optimized efficiency may be obtained.

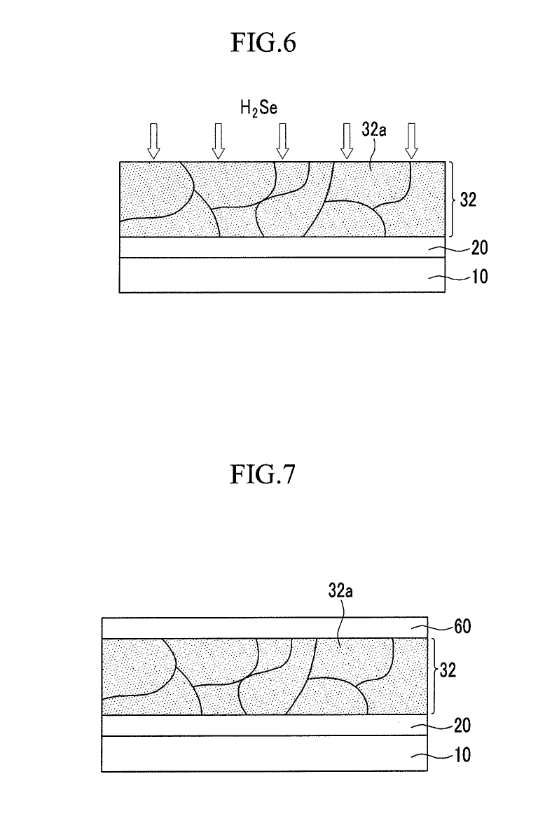

Referring to FIG. 6, selenium (Se) is supplied while heat-treating the third layer 50 and the preliminary light absorption layer 31 to form a light absorption layer 32. Here, gallium (Ga) or indium (In) and selenium (Se) included in the third layer 50 are reacted with the CIGS compound and the CuSe compound included in the preliminary light absorption layer 31, thereby forming a CIGS crystallization layer 32a in which the grain size is increased. Here, most of the CuSe compound is removed to prevent the solar cell from not operating when the CuSe compound as the conductive material remains inside the solar cell thereby functioning as a leakage path.

The CIGS crystallization layer 32a constitutes the light absorption layer 32, and the grain size of the CIGS crystallization layer 32a is larger than the grain size of the CIGS compound layer 31a included in the preliminary light absorption layer 31. Also, the CIGS crystallization layer 32a is densely positioned at the interface along with the first electrode 20 without a void.

The light absorption layer 32 functions as a P-type semiconductor substantially absorbing light.

Referring to FIG. 7, a buffer layer 60 is formed on the light absorption layer 32.

The buffer layer 60 is formed between the PN junction thereby having a function of smoothing the difference of lattice constants and energy bandgaps between the P-type semiconductor and the N-type semiconductor. Accordingly, the energy bandgap of the material used as the buffer layer 60 may have a middle value between the energy bandgap of the N-type semiconductor and the P-type semiconductor. The buffer layer 60 may be made of, for example, CdS, Zn(O,S,OH), In(OH)xSy, ZnInxSey, or ZnSe.

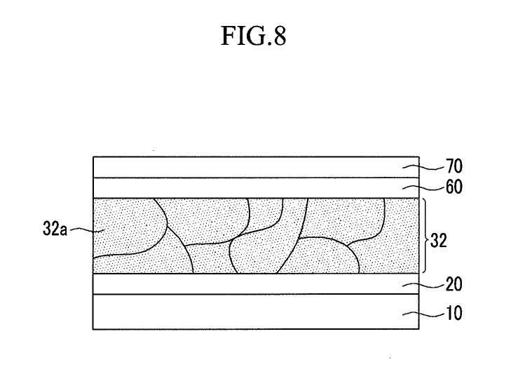

Referring to FIG. 8, a second electrode 70 is formed on the buffer layer 60. The second electrode 70 as the N-type semiconductor may be made of, for example, a transparent conductive material. The second electrode 70 may be formed of, for example, ZnO:Al.

In addition, an upper substrate may be formed on the second electrode 70.

In an exemplary embodiment of the present invention, the first electrode 20 is the reflective electrode and the second electrode 70 is the transparent electrode. However, exemplary embodiments of the present invention may be applied to a case in which the first electrode 20 is the transparent electrode and the second electrode 70 is the reflective electrode.

As described above, in the manufacturing method of the solar cell according to an exemplary embodiment of the present invention, when forming the precursor including copper, gallium, and indium, copper of an excessive amount is supplied, and the final composition ratio of copper, gallium, and indium is controlled in the process of adding gallium or indium such that voids are removed at the interface between the light absorption layer and the first electrode, and a CIGS crystallization layer having a large grain size may be formed. Accordingly, a solar cell having high light efficiency may be formed.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method for manufacturing a solar cell, comprising:
forming a first electrode on a substrate;
forming a precursor including copper (Cu), gallium (Ga), and indium (In), on the first electrode;
supplying selenium (Se) to the precursor to form a preliminary light absorption layer;
depositing at least one of gallium and indium on the preliminary light absorption layer;
supplying selenium (Se) to the preliminary light absorption layer deposited with the at least one of gallium and indium to form a light absorption layer; and
forming a second electrode on the light absorption layer.

2. The method of claim 1, wherein
the precursor is formed for a composition ratio corresponding to the copper/(gallium+indium) to be more than about 1.2.

3. The method of claim 2, wherein
the forming of the preliminary light absorption layer includes forming a CIGS (Cu, In, Ga, Se) compound and a copper selenide (CuSe) compound.

4. The method of claim 3, wherein
the depositing of at least one of gallium and indium on the preliminary light absorption layer comprises controlling a value of copper/(gallium+indium) corresponding to the composition ratio of the light absorption layer to be less than about 1.

5. The method of claim 4, wherein
the forming of the precursor includes:
forming a first layer including copper and at least one of gallium and indium on the first electrode; and
forming a second layer including at least one of gallium and indium on the first layer.

6. The method of claim 5, wherein
the forming of the first layer and the second layer comprises the use of sputtering.

7. The method of claim 1, wherein
the forming of the preliminary light absorption layer by supplying selenium (Se) to the precursor comprises a heat treatment.

8. The method of claim 7, wherein
the forming of the preliminary light absorption layer comprises forming a copper selenide (CuSe) compound, and the CuSe compound is in a liquid phase.

9. The method of claim 8, wherein
the forming of the light absorption layer comprises forming a GIGS (Cu, In, Ga, Se) compound by reacting the CuSe compound and at least one of gallium and indium.

10. The method of claim 1, wherein
the first electrode is formed of a reflective metal.

11. The method of claim 10, wherein
the second electrode is formed of a transparent conductive material.

12. The method of claim 1, further comprising
forming a buffer layer between the light absorption layer and the second electrode.

13. The method of claim 1, wherein
the forming of the preliminary light absorption layer includes forming a CIGS (Cu, In, Ga, Se) compound and a copper selenide (CuSe) compound.

14. The method of claim 13, wherein
the CuSe compound is positioned at the interface between the CIGS compound and the first electrode.

15. The method of claim 14, wherein
the forming of the preliminary light absorption layer includes a heat treatment.

16. The method of claim 15, wherein
the CuSe compound exists as a liquid.

17. The method of claim 16, wherein
the depositing of at least one of gallium and indium on the preliminary light absorption layer comprises controlling a value of copper/(gallium+indium) corresponding to the composition ratio of the light absorption layer to be less than about 1.

18. The method of claim 1, wherein
the forming of the precursor comprises:
forming a first layer including copper and at least one of gallium and indium on the first electrode; and
forming a second layer including at least one of gallium and indium on the first layer.

19. The method of claim 18, wherein
the precursor is formed for a composition ratio corresponding to the copper/(gallium+indium) to be more than about 1.2.

20. The method of claim 19, wherein
the depositing of at least one of gallium and indium on the preliminary light absorption layer comprises controlling a value of copper/(gallium+indium) corresponding to the composition ratio of the light absorption layer to be less than about 1.
